(19) United States
(12) Patent Application Publication
(10) Pub. No.: US 2025/0204167 A1
(43) Pub. Date: Jun. 19, 2025

(54) DISPLAY DEVICE

(71) Applicant: Japan Display Inc., Tokyo (JP)

(72) Inventors: Sho YANAGISAWA, Tokyo (JP); Toshimasa YONEKURA, Tokyo (JP); Hirofumi FUNAKOSHI, Tokyo (JP)

(73) Assignee: Japan Display Inc., Tokyo (JP)

(21) Appl. No.: 18/985,102

(22) Filed: Dec. 18, 2024

(30) Foreign Application Priority Data
Dec. 19, 2023 (JP) 2023-213895

(51) Int. Cl. H10K 59/122; H10K 59/35

(52) U.S. Cl. CPC H10K 59/122; H10K 59/352; H10K 59/353

(57) ABSTRACT

According to one embodiment, a display device comprises a lower electrode, a rib including a plurality of pixel apertures overlapping the lower electrode, a partition, a plurality of organic layers in contact with the lower electrode respectively through the plurality of pixel apertures and emitting light according to an application of a voltage, and a plurality of upper electrodes respectively covering the plurality of organic layers. The partition includes a lower portion provided above the rib, an upper portion having an end portion protruding relative to a side surface of the lower portion, a plurality of apertures respectively overlapping the plurality of pixel apertures, and a partition provided between the plurality of pixel apertures.

### CROSS-REFERENCE TO RELATED APPLICATIONS

This application is based upon and claims the benefit of priority from Japanese Patent Application No. 2023-213895, filed Dec. 19, 2023, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique which can improve yields is required.

### BRIEF DESCRIPTION OF THE DRAWINGS

FIG. 1 is a view showing a configuration example of a display device of the first embodiment.

FIG. 2 is a schematic plan view showing an example of a layout of subpixels of the first embodiment.

FIG. 3 is a schematic cross-sectional view of the display device along line III-III in FIG. 2.

FIG. 4 is a view showing an example of a layer structure applicable to organic layers.

FIG. 5 is a schematic plan view of a partition shown in FIG. 2.

FIG. 6 is a schematic cross-sectional view of the display device along line IV-IV in FIG. 2.

FIG. 7 is a schematic plan view showing another example of the layout of the subpixels of the first embodiment.

FIG. 8 is a schematic plan view of a partition shown in FIG. 7.

FIG. 9 is a schematic plan view showing an example of a layout of subpixels of the second embodiment.

FIG. 10 is a schematic plan view of a partition shown in FIG. 9.

FIG. 11 is a schematic plan view showing another example of the layout of the subpixels of the second embodiment.

FIG. 12 is a schematic plan view of a partition shown in FIG. 11.

### DETAILED DESCRIPTION

In general, according to one embodiment, a display device comprises: a first lower electrode; a rib including a plurality of first pixel apertures overlapping the first lower electrode; a partition; a plurality of first organic layers in contact with the first lower electrode respectively through the plurality of first pixel apertures and emitting light according to an application of a voltage; and a plurality of first upper electrodes respectively covering the plurality of first organic layers. The partition includes a lower portion provided above the rib and an upper portion having an end portion protruding relative to a side surface of the lower portion. In addition, the partition includes a plurality of first apertures respectively overlapping the plurality of first pixel apertures, and a first partition provided between the plurality of first pixel apertures.

According to another embodiment, a display device comprises: a first lower electrode; a rib including a first pixel aperture overlapping the first lower electrode; a partition; a first organic layer in contact with the first lower electrode through the first pixel aperture and emitting light according to an application of a voltage; and a first upper electrode covering the first organic layer. The partition includes a lower portion provided above the rib and an upper portion having an end portion protruding relative to a side surface of the lower portion. In addition, the partition includes a first aperture overlapping the first pixel aperture, and a first partition overlapping the first pixel aperture and spaced apart from an edge portion of the first aperture.

The present embodiment can provide a display device capable of improving yields.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction along the X-axis is referred to as an X direction (a second direction) and a direction along the Y-axis is referred to as a Y direction (a first direction), and a direction along the Z-axis is referred to as a Z direction. The Z direction is the normal direction of a plane including the X direction and the Y direction. When various elements are viewed parallel to the Z direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

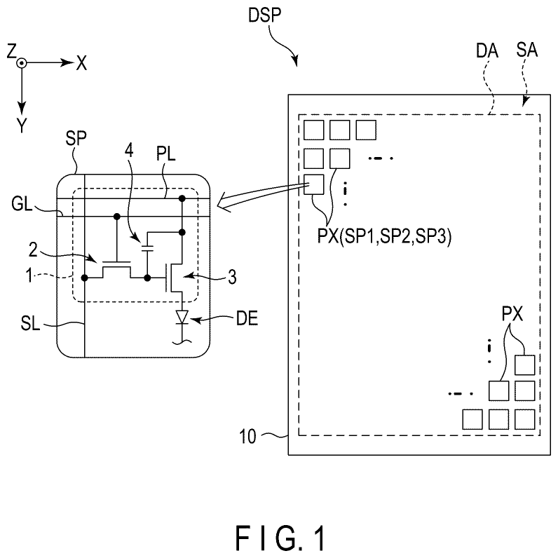

FIG. 1 is a view showing a configuration example of a display device DSP of the first embodiment. The display device DSP comprises an insulating substrate 10. The substrate 10 has a display area DA which displays an image and a surrounding area SA around the display area DA. The substrate 10 may be glass or a resinous film having flexibility.

In the present embodiment, the substrate 10 has a rectangular shape as seen in plan view. The shape of the substrate 10 in plan view is not limited to a rectangle and may be another shape such as a square, a circle or an elliptic shape.

The display area DA comprises a plurality of pixels PX arranged in a matrix in the X direction and the Y direction. Each pixel PX includes a plurality of subpixels SP which display different colors. The present embodiment assumes a case where each pixel PX includes a blue subpixel SP1, a green subpixel SP2, and a red subpixel SP3. However, each pixel PX may include a subpixel SP which exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines GL supplying a scanning signal to the pixel circuit 1 of each subpixel SP, a plurality of signal lines SL supplying a video signal to the pixel circuit 1 of each subpixel SP, and a plurality of power lines PL are provided in the display area DA. In the example of FIG. 1, the scanning lines GL and the power lines PL extend in the X direction, and the signal lines SL extend in the Y direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. The drain electrode of the drive transistor 3 is connected to the display element DE.

The configuration of the pixel circuit 1 is not limited to the shown example. For example, the pixel circuit 1 may comprise more thin-film transistors and capacitors.

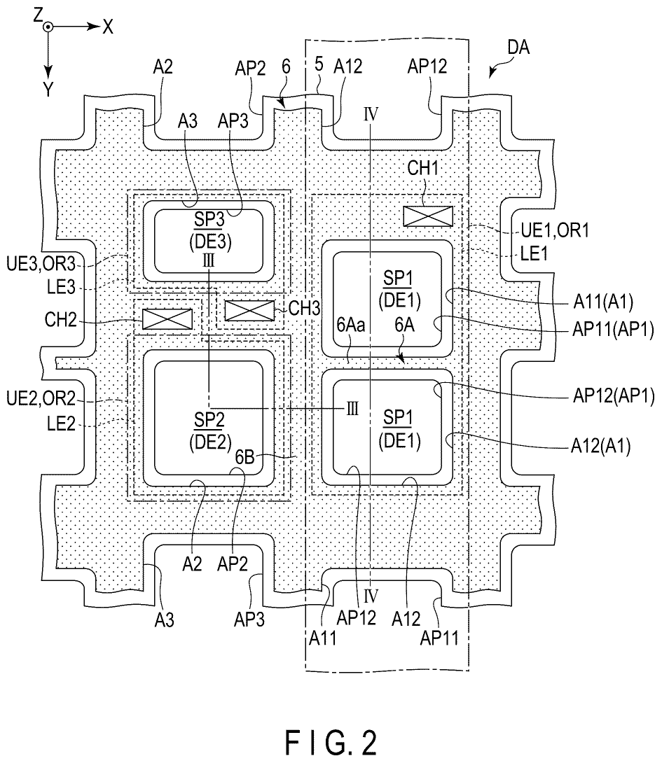

FIG. 2 is a schematic plan view showing an example of the layout of subpixels SP1, SP2, and SP3 of the first embodiment. In the example shown in FIG. 2, the subpixels SP2 and SP3 are arranged with the subpixels SP1 in the X direction. Further, the subpixels SP2 and SP3 are arranged in the Y direction.

When the subpixels SP1, SP2 and SP3 are arranged in this layout, in the display area DA, a row in which the subpixels SP2 and SP3 are alternately arranged in the Y direction and a row in which the plurality of subpixels SP1 are repeatedly arranged in the Y direction are formed.

The layout of the subpixels SP1, SP2, and SP3 and the size of the subpixels SP1, SP2, and SP3 are not limited to the example of FIG. 2. As another example, the subpixels SP1, SP2, and SP3 may be arranged in the X direction. Further, at least two of the subpixels SP1, SP2, and SP3 may have the same size.

A rib 5 is arranged in the display area DA. The rib 5 includes pixel apertures AP1, AP2, and AP3 in the subpixels SP1, SP2, and SP3, respectively. The pixel aperture AP1 includes pixel apertures AP11 and AP12. Each of the pixel apertures AP11 and AP12 is an example of a first pixel aperture. The pixel aperture AP2 is an example of a second pixel aperture.

In the example of FIG. 2, the pixel apertures AP11 and AP12 are arranged in the Y direction. Further, the pixel aperture AP11 is adjacent to the pixel aperture AP3 in the X direction. The pixel aperture AP12 is adjacent to the pixel aperture AP2 in the X direction.

In the example of FIG. 2, the area of the pixel aperture AP11 is equivalent to the area of the pixel aperture AP12. In addition, each of the area of the pixel apertures AP11 and AP12 is smaller than the area of the pixel aperture AP2 and greater than the area of the pixel aperture AP3. Further, the sum area (a total area of the aperture AP1) combining the area of the pixel aperture AP11 and the area of the pixel aperture AP12 is greater than each of the pixel apertures AP2 and AP3.

Further, the area of the pixel aperture AP11 may be different from the area of the pixel aperture AP12. In addition, the area of each of the pixel apertures AP11 and AP12 may be greater than or smaller than the area of each of the pixel apertures AP2 and AP3.

A partition 6 is provided in the display area DA. The partition 6 is located above the rib 5 to entirely overlap the rib 5. In the example of FIG. 2, the partition 6 has the same planar shape as the rib 5. That is, the partition 6 includes apertures A1, A2, and A3 in the respective subpixels SP1, SP2, and SP3. The aperture A1 includes apertures A11 and A12. The apertures A11, A12, A2, and A3 respectively overlap the pixel apertures AP11, AP12, AP2, and AP3. Each of the apertures A11 and A12 is an example of a first aperture. The aperture A2 is an example of a second aperture.

In the example of FIG. 2, the area of the aperture A11 is equivalent to the area of the aperture A12. In addition, the area of each of the apertures A11 and A12 is smaller than the area of the aperture A2 and is greater than the area of the aperture A3. Further, the sum area (the total area of the aperture A1) combining the area of the aperture A11 and the area of the aperture A12 is greater than each of the apertures A2 and A3.

The area of the aperture A11 may be different from the area of the aperture A12. In addition, the area of each of the apertures A11 and A12 may be greater or smaller than the area of each of the apertures A2 and A3.

The partition 6 includes a partition 6A (a first partition) and a partition 6B (a second partition). The partition 6A is provided between the pixel aperture AP11 and the pixel aperture AP12. In the example of FIG. 2, the partition 6A is constituted by a first portion 6Aa, which extends in the X direction between the aperture A11 and the aperture A12.

The partition 6B is provided between the pixel aperture AP1 and the pixel aperture AP2. In the example of FIG. 2, the partition 6B is provided between the pixel aperture AP12 and the pixel aperture AP2. The partition 6B extends in the Y direction and intersects the partition 6A. In the example of FIG. 2, the partition 6B in orthogonal to the first portion 6Aa of the partition 6A. However, the configuration is not limited to this example.

The subpixel SP1 comprises a lower electrode (a first lower electrode) LE1, an upper electrode (a first upper electrode) UE1, and an organic layer (a first organic layer) OR1 that overlap the pixel aperture AP1. The subpixel SP2 comprises a lower electrode (a second lower electrode) LE2, an upper electrode (a second upper electrode) UE2, and an organic layer (a second organic layer) OR2 that overlap the pixel aperture AP2. The subpixel SP3 comprises a lower electrode LE3, an upper electrode UE3, and an organic layer OR3 that overlap the pixel aperture AP3.

Portions which overlap the pixel aperture AP1 of the lower electrode LE1, the upper electrode UE1, and the organic layer OR1 constitute a display element DE1 of the subpixel SP1. Portions which overlap the pixel aperture AP2 of the lower electrode LE2, the upper electrode UE2, and the organic layer OR2 constitute a display element DE2 of the subpixel SP2. Portions which overlap the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later.

The pixel circuits 1 (shown in FIG. 1) of the subpixels SP1, SP2, and SP3 are provided below the respective lower electrodes LE1, LE2, and LE3. The lower electrode LE1 is connected to the pixel circuit 1 of the subpixel SP1 through a contact hole CH1. The lower electrode LE2 is connected to the pixel circuit 1 of the subpixel SP2 through a contact hole CH2. The lower electrode LE3 is connected to the pixel circuit 1 of the subpixel SP3 through a contact hole CH3. In the example of FIG. 2, the contact holes CH1, CH2, and CH3 entirely overlap the rib 5 and the partition 6. However, the configuration is not limited to this example.

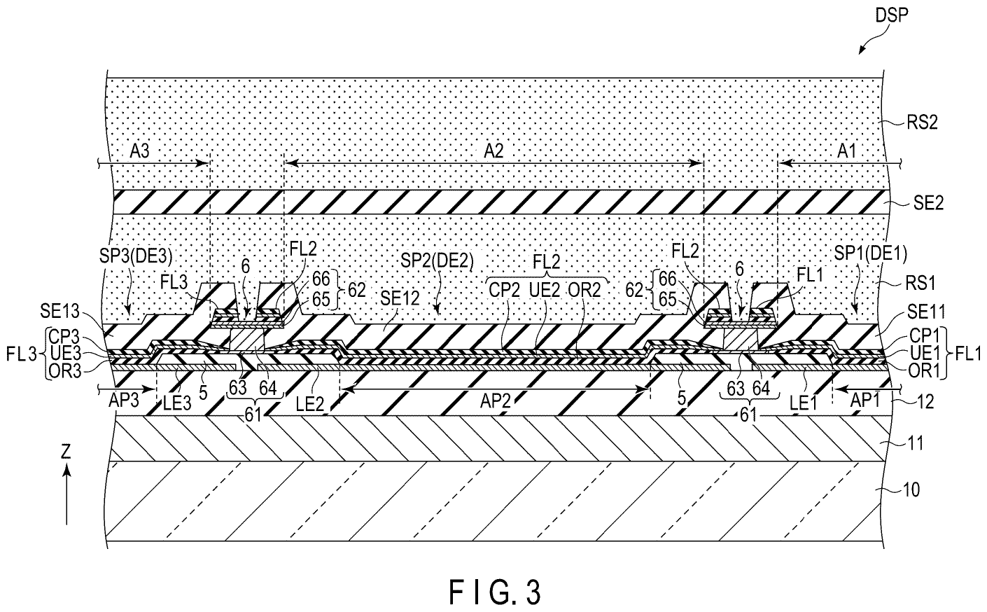

FIG. 3 is a schematic cross-sectional view of the display device DSP along the line III-III in FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film which planarizes irregularities formed by the circuit layer 11.

The lower electrodes LE1, LE2, and LE3 are provided on the organic insulating layer 12. The rib 5 is provided on the organic insulating layer 12 and the lower electrodes LE1, LE2, and LE3. End portions of the lower electrodes LE1, LE2, and LE3 are covered with the rib 5. Although not shown in the section of FIG. 3, the lower electrodes LE1, LE2, and LE3 are connected to the respective pixel circuits 1 of the circuit layer 11 through the respective contact holes CH1, CH2, and CH3 (shown in FIG. 2) provided in the organic insulating layer 12.

The partition 6 includes a conductive lower portion 61 provided on the rib 5 and an upper portion 62 provided on the lower portion 61. The upper portion 62 has the width greater than the width of the lower portion 61. This configuration allows the both end portions of the upper portion 62 to protrude relative to the side surfaces of the lower portion 61. This shape of the partition 6 is called an overhang shape.

In the example of FIG. 3, the lower portion 61 has a bottom layer 63 provided on the rib 5, and a stem layer 64 provided on the bottom layer 63. For example, the bottom layer 63 is formed to be thinner than the stem layer 64. In the example of FIG. 3, the both end portions of the bottom layer 63 protrude relative to the side surfaces of the stem layer 64.

In the example of FIG. 3, the upper portion 62 includes a first top layer 65 and a second top layer 66. The first top layer 65 is provided on the stem layer 64. The second top layer 66 is provided on the first top layer 65. As shown in the figure, the second top layer 66 may be formed to be thinner than the first top layer 65. In addition, the second top layer 66 may have the width smaller than the width of the first top layer 65. When the partition 6 has the configuration shown in FIG. 3, each of the apertures A11, A12, A2, and A3 shown in FIG. 2 corresponds to the area surrounded by the end portions of the first top layer 65.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surfaces of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

A part of the stacked film FL1 is located on the upper portion 62. This part is spaced apart from a part of the stacked film FL1 which is located around the partition 6 (in other words, from the part which constitutes the display element DE1). Similarly, a part of the stacked film FL2 is located on the upper portion 62. This part is spaced apart from a part of the stacked film FL2 which is located around the partition 6 (in other words, from the part which constitutes the display element DE2). Further, a part of the stacked film FL3 is located on the upper portion 62. This part is spaced apart from a part of the stacked film FL3 which is located around the partition 6 (in other words, from the part which constitutes the display element DE3).

Sealing layers SE11, SE12 and SE13 are provided in the subpixels SP1, SP2 and SP3, respectively. The sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example of FIG. 3, the stacked film FL1 and the sealing layer SE11 located on the partition 6 between the subpixels SP1 and SP2 are spaced apart from the stacked film FL2 and the sealing layer SE12 located on this partition 6. The stacked film FL1 and the sealing layer SE11 located on the partition 6 between the subpixels SP1 and SP3 are spaced apart from the stacked film FL3 and the sealing layer SE13 located on this partition 6.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib 5 and the sealing layers SE11, SE12, SE13 and SE2 is formed of an inorganic insulating material such as silicon nitride (SiNx), silicon oxide (SiOx), silicon oxynitride (SiON), or aluminum oxide (Al₂O₃). For example, the rib 5 is formed of silicon oxynitride, and each of the sealing layers SE11, SE12, SE13, and SE2 is formed of silicon nitride. Each of the resin layers RS1 and RS2 is formed of, for example, a resinous material (an organic insulating material) such as epoxy resin or acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO), or indium gallium zinc oxide (IGZO).

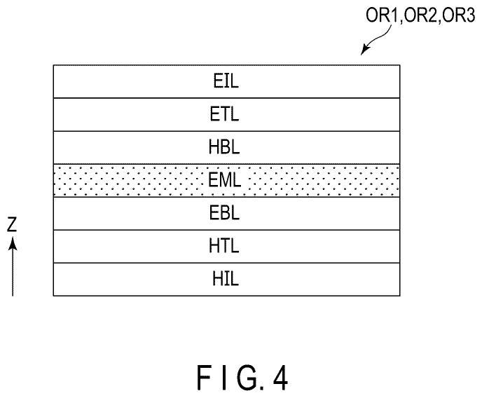

FIG. 4 is a view showing an example of a layer structure applicable to the organic layers OR1, OR2, and OR3. Each of the organic layers OR1, OR2, and OR3 is formed of a plurality of thin films including a light emitting layer EML. The present embodiment assumes a case where each of the organic layers OR1, OR2, and OR3 comprises a structure in which a hole injection layer HIL, a hole transport layer HTL, an electron blocking layer EBL, the light emitting layer EML, a hole blocking layer HBL, an electron transport layer ETL, and an electron injection layer EIL are stacked in this order in the Z direction. Each of the organic layers OR1, OR2, and OR3 may comprise another structure such as a tandem structure including a plurality of light emitting layers EML.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indexes different from each other. For example, the refractive indexes of these transparent layers are different from the refractive indexes of the upper electrodes UE1, UE2, and UE3 and the refractive indexes of the sealing layers SE11, SE12, and SE13. The cap layers CP1, CP2, and CP3 function as optical adjustment layers which improve the extraction efficiency of the light emitted from the organic layers OR1, OR2, and OR3, respectively. At least one of the cap layers CP1, CP2, and CP3 may be omitted.

For example, each of the bottom layer 63 and the stem layer 64 of the partition 6 is formed of metal materials different from each other. For the metal material of the bottom layer 63, for example, molybdenum (Mo), titanium (Ti), titanium nitride (TiN), a molybdenum-tungsten alloy (MoW), or a molybdenum-niobium alloy (MoNb) can be used. For the metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may comprise a stacked layer structure in which a plurality of layers are stacked. The stem layer 64 may include a layer formed of an insulating material.

For example, the first top layer 65 of the partition 6 is formed of a metal material and the second top layer 66 is formed of a transparent conductive oxide. For the metal material of the first top layer 65, for example, titanium, titanium nitride, molybdenum, tungsten, a molybdenum-tungsten alloy, or a molybdenum-niobium alloy may be used. For the conductive oxide of the second top layer 66, for example, ITO or IZO may be used. The upper portion 62 may comprise a single-layer structure formed of a specific material. The upper portion 62 may further include a layer formed of an insulating material.

A common voltage is applied to the partition 6. This common voltage is applied to each of the upper electrodes UE1, UE2, and UE3 in contact with the lower portions 61. That is, the partition 6 functions as lines which apply common voltage to the upper electrodes UE1, UE2, and UE3. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. More specifically, when a potential difference is formed between the lower electrode LE1 and the upper electrode UE1, the light emitting layer EML of the organic layer OR1 emits light in a blue wavelength range. When a potential difference is formed between the lower electrode LE2 and the upper electrode UE2, the light emitting layer EML of the organic layer OR2 emits light in a green wavelength range. When a potential difference is formed between the lower electrode LE3 and the upper electrode UE3, the light emitting layer EML of the organic layer OR3 emits light in a red wavelength range. As another example, the light emitting layer EML of the organic layer OR2 may emit light in a red wavelength range, and the light emitting layer EML of the organic layer OR3 may emit light in a green wavelength range.

As another example, the light emitting layers EML of the organic layers OR1, OR2, and OR3 may emit light exhibiting the same color (for example, white). In this case, the display device DSP may comprise a color filter that converts the light emitted from the light emitting layers EML into light of the colors corresponding to the respective subpixels SP1, SP2, and SP3. In addition, the display device DSP may comprise a layer including quantum dots that are excited by the light emitted from the light emitting layers EML to generate the light of the colors corresponding to the subpixels SP1, SP2, and SP3.

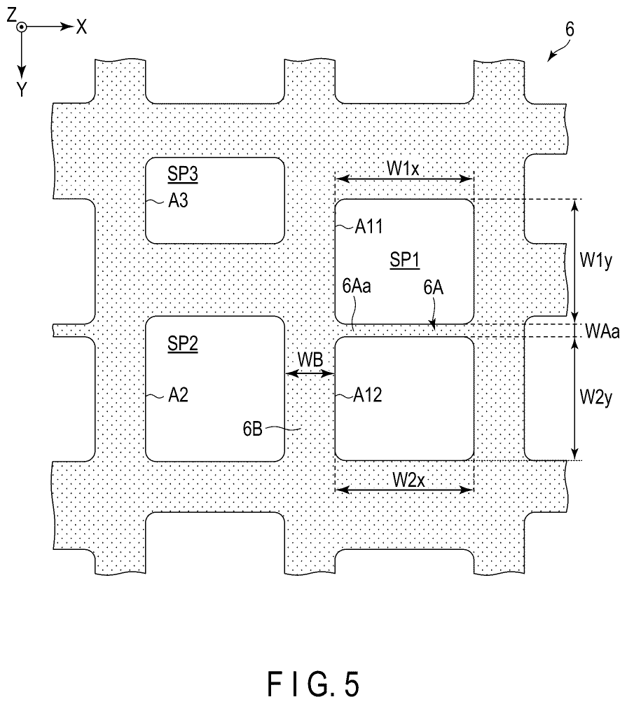

FIG. 5 is a schematic plan view of the partition 6 shown in FIG. 2. Here, as show in FIG. 5, the width along the X direction of the aperture A11 is defined as a width W1x, and the width along the Y direction of the aperture A11 is defined as a width W1y. Similarly, the width along the X direction of the aperture A12 is defined as a width W2x, and the width along the Y direction of the aperture A12 is defined as a width W2y. In addition, the width along the Y direction of the first portion 6Aa is defined as a width WAa. Further, the width along the X direction of the partition 6B is defined as a width WB.

In the present embodiment, the width W1x is equivalent to the width W2x (W1x=W2x), and the width W1y is equivalent to the width W2y (W1y=W2y). That is, in the example of FIG. 5, the area of the aperture A11 is equivalent to the area of the aperture A12. The magnitude relationship of the width W1x and the width W2x and the magnitude relationship of the width W1y and the width W2y are not limited to this example. The width W1x may be different from the width W2x. The width W1y may be different from the width W2y.

In the present embodiment, the sum of the widths W1y, W2y, and WAa (W1y+W2y+WAa) is greater than at least one of the widths W1x and W2x (greater than both of the widths W1x and W2x in the example of FIG. 5). The width WAa is smaller than the width WB (WAa<WB).

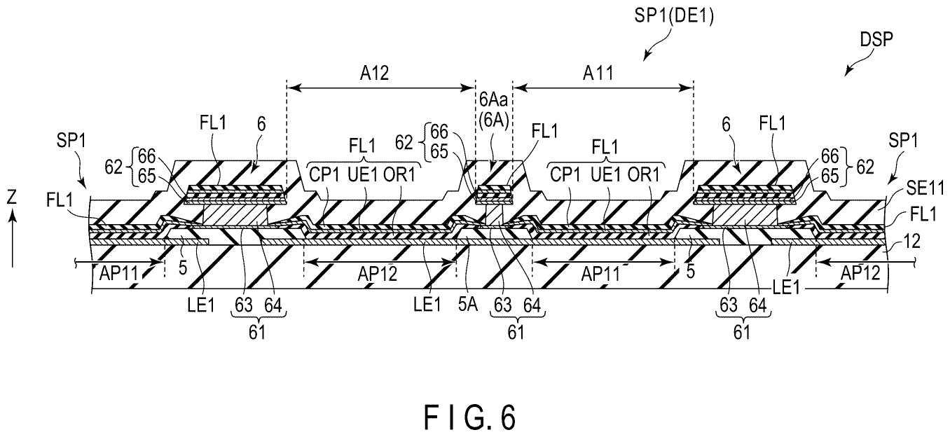

FIG. 6 is a schematic cross-sectional view of the display device DSP along the line IV-IV in FIG. 2. The illustration of the substrate 10, the circuit layer 11, the resin layer RS1, the sealing layer SE2, and the resin layer RS2 is omitted.

In the following descriptions, a portion of the rib 5 that overlaps the partition 6A is called a rib 5A. The rib 5A is provided on the lower electrode LE1. The first portion 6Aa is provided on the rib 5A. The first portion 6Aa is provided between the pixel aperture AP11 and the pixel aperture AP12. Similarly to the other portions of the partition 6, the partition 6A (the first portion 6Aa) has the overhang shape. In the subpixel SP1, the stacked film FL1 is divided by the first portion 6Aa.

The two organic layers OR1 divided by the first portion 6Aa are connected to the lower electrode LE1 through the respective pixel apertures AP11 and AP12. The two upper electrodes UEl divided by the first portion 6Aa respectively cover the two organic layers OR1. The two cap layers CP1 divided by the first portion 6Aa respectively cover the two upper electrodes UE1. A part of the stacked film FL1 is located on the upper portion 62 of the partition 6A. This portion is spaced apart from the portion of the stacked film FL1 that is located around the partition 6A (in other words, the portion which constitutes the display element DE1). The sealing layer SE11 continuously covers the partition 6A and the cap layer CP1.

Here, some effects exhibited by the present embodiment will be described. In the manufacturing process of the display device DSP, the stacked film FL1 is formed in the entire display area DA by vapor deposition. Further, the sealing layer SE11 covering the stacked film FL1 is formed. Next, patterning on these stacked film FL1 and sealing layer SE11 is conducted. More specifically, portions of the stacked film FL1 and the sealing layer SE11 that are provided in the subpixel SP1 remain, and portions of the stacked film FL1 and the sealing layer SE11 that are provided in the subpixels SP2 and SP3 are removed. Thereafter, the stacked film FL2 and the sealing layer SE12 are formed in the subpixel SP2 in the same process. Further, the stacked film FL3 and the sealing layer SE13 are formed in the subpixel SP3 in the same process.

The adherence of the stacked film FL1, which has been formed by vapor deposition, to the lower electrode LE1 is weak. Thus, the stacked film FL1 may be detached during the manufacturing process of the display device DSP. This detachment may decrease the yield of the display device DSP.

The detachment of the stacked film FL1 tends to occur in an area where the stacked film FL1 is continuously and broadly formed. With respect to this point, in the display device DSP of the present embodiment, the aperture A1 is divided into the apertures A11 and A12 by the first portion 6Aa of the partition 6A. Thus, the stacked film FL1 formed in the subpixel SP1 is divided by the first portion 6Aa. Therefore, compared to a case where the partition 6A is not provided, an area in which the stacked film FL1 is continuously formed in the subpixel SP1 is smaller. Thus, the detachment of the stacked film FL1 is less likely to occur. Therefore, the yield of the display device DSP can be improved.

In the present embodiment, the area of the aperture A1 (the sum of the areas of the apertures A11 and A12) is greater than the area of each of the apertures A2 and A3. Therefore, among the apertures A1, A2, and A3, the detachment tends to occur in the aperture A1. Therefore, by dividing the aperture A1 by means of the partition 6A, the risk of the detachment can be efficiently suppressed. However, the configuration is not limited to this example. At least one of the apertures A2 and A3 may be divided by the partition. This further increases the effect of suppressing the detachment.

Further, in the present embodiment, the width WAa of the first portion 6Aa dividing the stacked film FL1 is smaller than the width WB of the partition 6B provided between the pixel aperture AP1 and the pixel aperture AP2. As the width WAa of the first portion 6Aa increases, the width of the rib 5A increases. Thus, the pixel aperture AP1 decrease in its size, decreasing the aperture ratio of the subpixel SP1. Therefore, the decrease in the aperture ratio of the subpixel SP1 can be suppressed by decreasing the width WAa of the first portion 6Aa.

In the present embodiment, the lower electrode LE1 and the aperture A1 have shapes elongating in the Y direction. In addition, the first portion 6Aa extends in the X direction. Further, the aperture A1 is divided by the first portion 6Aa such that the apertures A11 and A12 are arranged in the Y direction. The configuration is not limited to this example. The first portion 6Aa may extend in the Y direction. That is, the aperture A1 may be divided by the first portion 6Aa such that the apertures A11 and A12 are arranged in the X direction.

In the present embodiment, the aperture A1 is divided into two portions by the partition 6A. The aperture A1 may be divided into three portions or more. In those cases, the aperture may be divided by a plurality of partitions parallel to each other or by a plurality of partitions intersecting each other, as described later.

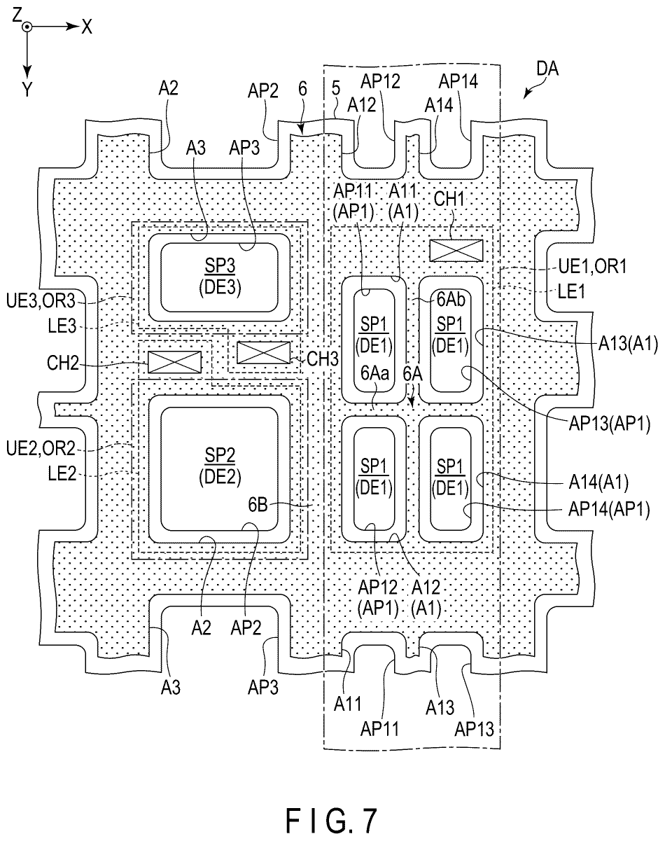

FIG. 7 is a schematic plan view showing another example of the layout of the subpixels SP1, SP2, and SP3 of the first embodiment. In each example, the same or similar elements as those of the display device DSP described above are referred to by the same reference numbers and explanations of these elements are omitted.

The pixel aperture AP1 includes the pixel apertures AP11 and AP12 and pixel apertures AP13 and AP14. In the example of FIG. 7, the pixel apertures AP11 and AP13 are arranged in the X direction, the pixel apertures AP12 and A14 are arranged in the X direction, the pixel apertures A11 and AP12 are arranged in the Y direction, and the pixel apertures AP13 and AP14 are arranged in the Y direction. In the example of FIG. 7, the pixel apertures AP11, AP12, AP13, and AP14 have the same area. The pixel apertures AP11, AP12, AP13, and AP14 may have areas different from one another.

The aperture A1 includes the apertures A11, A12, A13, and A14. The apertures A11, A12, A13, and A14 respectively overlap the pixel apertures AP11, AP12, AP13, and AP14. In the example of FIG. 7, the apertures A11, A12, A13, and A14 have the same area. The apertures A11, A12, A13, and A14 may have areas different from one another.

Similarly to the example of FIG. 2, the partition 6A includes the first portion 6Aa. The first portion 6Aa is provided between the pixel aperture AP11 and the pixel aperture AP12 and between the pixel aperture AP13 and the pixel aperture AP14. The partition 6A further includes a second portion 6Ab. The second portion 6Ab is provided between the pixel aperture AP11 and the pixel aperture AP13 and between the pixel aperture AP12 and the pixel aperture AP14. In the example of FIG. 7, the first portion 6Aa extends in the X direction. In addition, the second portion 6Ab extends in the Y direction and intersects the first portion 6Aa.

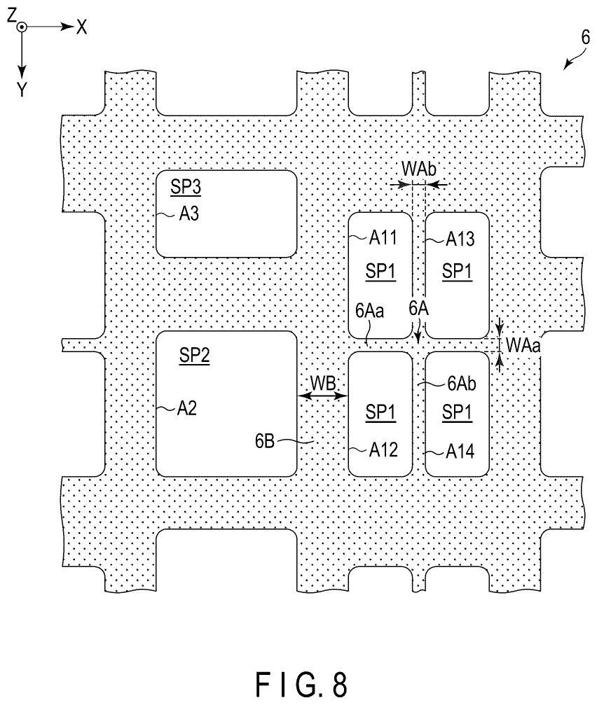

FIG. 8 is a schematic plan view of the partition shown in FIG. 7. Here, as shown in FIG. 8, the width along the X direction of the second portion 6Ab is defined as a width WAb. In the example of FIG. 8, the width WAb is smaller than the width WB (WAb<WB). Similarly to the width WAa of the first portion 6Aa, the decrease in the aperture ratio of the subpixel SP1 can be suppressed by decreasing the width WAb of the second portion 6Ab.

In the examples of FIG. 7 and FIG. 8, the aperture A1 is divided into four portions by the first portion 6Aa and the second portion 6Ab. That is, compared to the example of FIG. 2, the number of the divided apertures is greater. Thus, the detachment of the stacked film FL1 is even less likely to occur. The configuration of the partition 6A shown in FIG. 7 and FIG. 8 can be applied to the subpixels SP2 and SP3.

### Second Embodiment

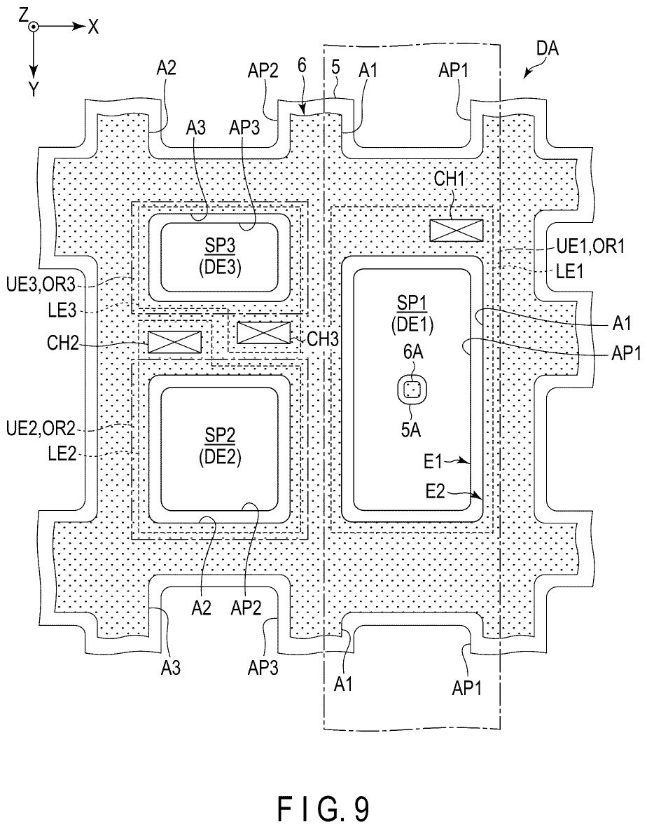

FIG. 9 is a schematic plan view showing an example of the layout of subpixels SP1, SP2, and SP3 of the second embodiment. The same elements as those of the display device DSP of the first embodiment are denoted by the same reference numbers and overlapping descriptions of these elements are omitted.

In the present embodiment, a rib 5 includes an island-like shaped rib 5A spaced apart from an edge portion E1 of a pixel aperture AP1. The rib 5A is provided on a lower electrode LE1. A partition 6 overlaps the pixel aperture AP1 and includes an island-like shaped partition 6A spaced apart from an edge portion E2 of an aperture A1. The partition 6A is provided on the rib 5A. Each of the rib 5A and the partition 6A has a shape in which the corner portion of a rectangular shape is rounded in plan view. The corner portion of each of the rib 5A and the partition 6A may have a right angle. The rib 5A and the partition 6A may have a circular shape or an elliptic shape. In the example of FIG. 9, the area of the aperture A1 is greater than the area of the aperture A2. The pixel aperture AP1 is an example of the first pixel aperture. The aperture A1 is an example of the first aperture. The partition 6A is an example of a first partition.

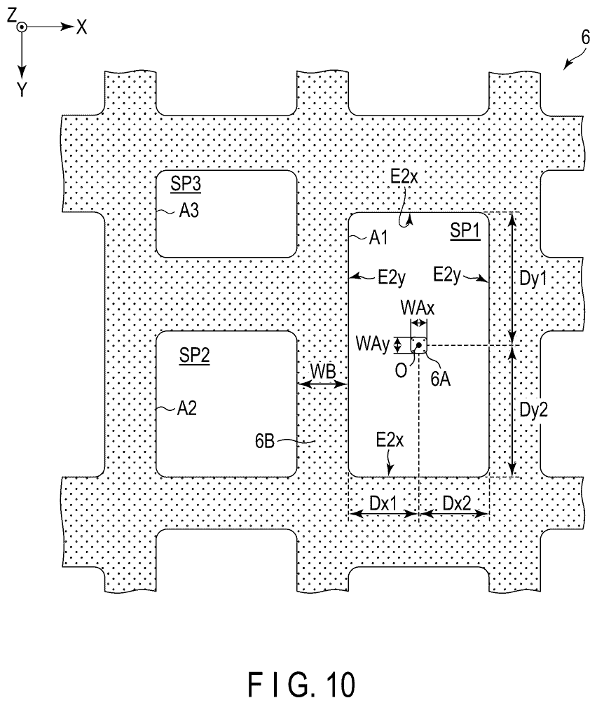

FIG. 10 is a schematic plan view of the partition 6 shown in FIG. 9. Here, as shown in FIG. 10, distances between respective two sides E2y of the edge portion E2 of the aperture A1 that are parallel to the Y direction and are provided to sandwich the partition 6A and a center O of the partition 6A are respectively defined as a distance Dx1 and a distance Dx2. In addition, distances between respective two sides E2x of the edge portion E2 of the aperture A1 that are parallel to the X direction and are provided to sandwich the partition 6A and a center O of the partition 6A are respectively defined as a distance Dy1 and a distance Dy2. Further, the width along the X direction of the partition 6A is defined as a width WAx, and the width along the Y direction of the partition 6A is defined as a width WAy.

In the present embodiment, the distance Dx1 is equivalent to the distance Dx2 (Dx1=Dx2), and the distance Dy1 is equivalent to the distance Dy2 (Dy1=Dy2). That is, the partition 6A is provided at the center of the aperture A11 in both the X direction and the Y direction. The configuration is not limited to the above example. The partition 6A may be arranged at positions shifted from the center of the aperture A11. The sum of the distance Dy1 and the distance Dy2 is greater than the sum of the distance Dx1 and the distance Dx2 (Dy1+Dy2>Dx1+Dx2). Each of the width WAx and the width WAy is smaller than the width WB (WAx, WAy<WB).

Similarly to the first embodiment, the second embodiment can suppress the detachment of the stacked film and improve the yield of the display device DSP.

Further, the present embodiment can increase the aperture ratio of the subpixel SP1 to be greater than that in the first embodiment by making the partition 6A spaced apart from the edge portion of the aperture A1.

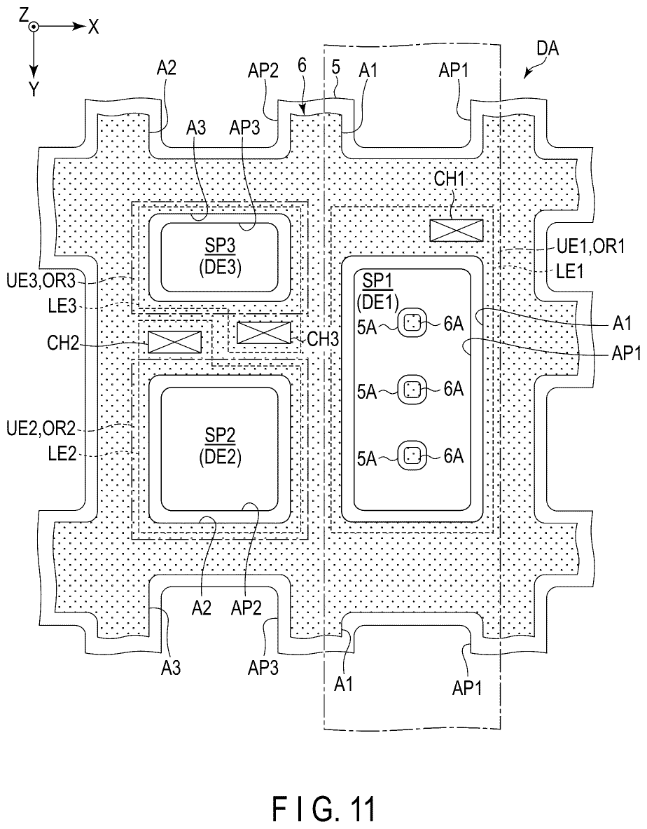

FIG. 11 is a schematic plan view showing another example of the layout of the subpixels SP1, SP2, and SP3 of the second embodiment. The rib 5 includes a plurality of ribs 5A. The partition 6 includes a plurality of partitions 6A. In the example of FIG. 11, each of the rib 5 and the partition 6 includes three ribs 5A and three partitions 6A. The number of each of the plurality of ribs 5A and the plurality of partitions 6A is not limited to three but may be two, or four or more.

In the example of FIG. 11, the plurality of ribs 5A and the plurality of partitions 6A are arranged along the Y direction. The plurality of ribs 5A and the plurality of partitions 6A may be arranged along the X direction or may not be arranged along either the X direction or the Y direction.

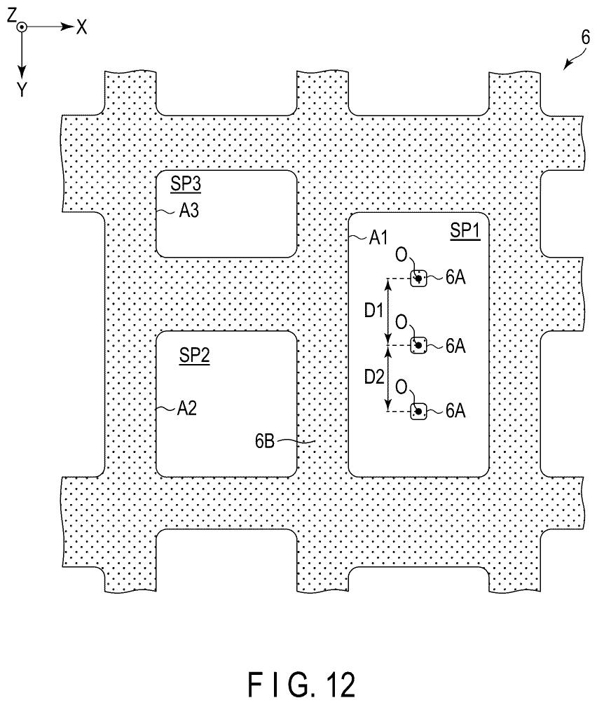

FIG. 12 is a schematic plan view of the partition 6 shown in FIG. 11. With respect to three partitions 6A arranged along the Y direction, distances between the centers O of respective two partition 6A that are adjacent to each other are respectively defined as a distance D1 and a distance D2. In the present embodiment, the distance D1 is equivalent to the distance D2 (D1=D2). That is, the plurality of partitions 6A are provided at regular intervals along the Y direction.

Similarly to the above embodiment, the present embodiment can suppress the removal of the stacked film and improve the yield of the display device DSP. In addition, in the present embodiment, the plurality of partitions 6A are arranged along a direction along which the aperture A1 elongates (the Y direction). Thus, the partitions 6A are moderately dispersed in the aperture A1. This configuration increases the effect of suppressing the detachment.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a first lower electrode;
a rib including a plurality of first pixel apertures overlapping the first lower electrode;
a partition including a lower portion provided above the rib and an upper portion having an end portion protruding relative to a side surface of the lower portion;
a plurality of first organic layers in contact with the first lower electrode respectively through the plurality of first pixel apertures and emitting light according to an application of a voltage; and
a plurality of first upper electrodes respectively covering the plurality of first organic layers, wherein
the partition includes:
a plurality of first apertures respectively overlapping the plurality of first pixel apertures; and
a first partition provided between the plurality of first pixel apertures.

2. The display device of claim 1, wherein
the first lower electrode has a shape elongating in a first direction,
two first apertures of the plurality of first apertures are arranged in the first direction, and
the first partition includes a first portion elongating in a second direction, the second direction intersecting the first direction between the two first apertures.

3. The display device of claim 2, wherein
a sum of widths along the first direction of the two first apertures and the first portion is greater than a width along the second direction of at least one of the two first apertures.

4. The display device of claim 2, further comprising:
a second lower electrode adjacent to the first lower electrode in the second direction;
a second organic layer emitting light in a color different from a color of the first organic layer, according to an application of a voltage; and
a second upper electrode covering the second organic layer, wherein
the rib includes a second pixel aperture overlapping the second lower electrode,
the second organic layer is in contact with the second lower electrode through the second pixel aperture, and
the partition further includes:
a second aperture overlapping the second pixel aperture; and
a second partition provided between the first pixel aperture and the second pixel aperture.

5. The display device of claim 4, wherein
a width along the first direction of the first portion is smaller than a width along the second direction of the second partition.

6. The display device of claim 4, wherein
the first portion is orthogonal to the second partition.

7. The display device of claim 4, wherein
an area of the first aperture is smaller than an area of the second aperture.

8. The display device of claim 4, wherein
a sum of areas of the plurality of first apertures is greater than an area of the second aperture.

9. The display device of claim 2, wherein
the two first apertures of the plurality of first apertures are arranged in the second direction,
the first partition includes a second portion provided between the two first apertures arranged in the second direction, and
the second portion intersects the first portion.

10. A display device, comprising:
a first lower electrode;
a rib including a first pixel aperture overlapping the first lower electrode;
a partition including a lower portion provided above the rib and an upper portion having an end portion protruding relative to a side surface of the lower portion;
a first organic layer in contact with the first lower electrode through the first pixel aperture and emitting light according to an application of a voltage; and
a first upper electrode covering the first organic layer, wherein
the partition includes:
a first aperture overlapping the first pixel aperture; and
a first partition overlapping the first pixel aperture and spaced apart from an edge portion of the first aperture.

11. The display device of claim 10, wherein
a width along a first direction of the first aperture is greater than a width along a second direction of the first aperture, the second direction intersecting the first direction, and
the first partition is provided at a center of the first aperture in the first direction.

12. The display device of claim 11, wherein
the first partition is provided at a center of the first aperture in the second direction.

13. The display device of claim 10, further comprising:
a second lower electrode adjacent to the first lower electrode;
a second organic layer emitting light in a color different from a color of the first organic layer, according to an application of a voltage; and
a second upper electrode covering the second organic layer, wherein
the rib includes a second pixel aperture overlapping the second lower electrode,
the second organic layer is in contact with the second lower electrode through the second pixel aperture, and
the partition further includes:
a second aperture overlapping the second pixel aperture; and
a second partition provided between the first pixel aperture and the second pixel aperture.

14. The display device of claim 13, wherein
a width of the first partition is smaller than a width of the second partition.

15. The display device of claim 13, wherein
an area of the first aperture is greater than an area of the second aperture.

16. The display device of claim 10, wherein
the partition includes a plurality of first partitions.

17. The display device of claim 16, wherein
a width along a first direction of the first aperture is greater than a width along a second direction of the first aperture, the second direction intersecting the first direction, and
the plurality of first partitions are arranged in the first direction.

18. The display device of claim 17, wherein
the plurality of first partitions are arranged at regular intervals.

19. The display device of claim 1, wherein
the first organic layer includes a light emitting layer emitting light exhibiting a blue color.

20. The display device of claim 4, wherein
the first organic layer includes a light emitting layer emitting light exhibiting a blue color, and
the second organic layer includes a light emitting layer emitting light exhibiting a green color or a red color.
